(19) United States
(12) Patent Application Publication
(10) Pub. No.: US 2026/0353727 A1
(43) Pub. Date: Nov. 5, 2026

(54) SEMICONDUCTOR DEVICE AND METHOD

(71) Applicant: Taiwan Semiconductor Manufacturing Co., Ltd., Hsinchu (TW)

(72) Inventor: Ka-Hing Fung, Zhudong Township (TW)

(21) Appl. No.: 19/734,683

(22) Filed: Jul. 8, 2026

Related U.S. Application Data
(63) Continuation of application No. 18/770,741, filed on Jul. 12, 2024.

(51) Int. Cl. H10D 62/10; H10D 30/01; H10D 30/43; H10D 30/67; H10D 84/01; H10D 84/03; H10D 84/85

(52) U.S. Cl. CPC H10D 62/121; H10D 30/014; H10D 30/43; H10D 30/6735; H10D 30/6757; H10D 84/0167; H10D 84/017; H10D 84/0188; H10D 84/038; H10D 84/85

(57) ABSTRACT

A semiconductor device and the method of forming the same are provided. The semiconductor device may include a first nanostructure and a second nanostructure, a gate structure between the first nanostructure and the second nanostructure, a first dielectric layer on a sidewall of the gate structure, and a second dielectric layer on the first dielectric layer. The first dielectric layer may include a first material and the second dielectric layer may include a second material different from the first material. The second dielectric layer may be in contact with the first nanostructure and the second nanostructure.

### CROSS-REFERENCE TO RELATED APPLICATIONS

This application is a continuation of U.S. Patent Application No. 18/770,741, filed on Jul. 12, 2024, and entitled “Semiconductor Device and Method,” which application is incorporated herein by reference.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of nanostructure field-effect transistors (nano-FETs) in a three-dimensional view, in accordance with some embodiments.

FIGS. 2, 3, 4, 5, 6A, 6B, 6C, 7A, 7B, 7C, 8A, 8B, 8C, 9A, 9B, 9C, 10A, 10B, 10C, 11A, 11B, 11C, 12A, 12B, 12C, 12D, 13A, 13B, 13C, 14A, 14B, 14C, 15A, 15B, 15C, 16A, 16B, 16C, 17A, 17B, 17C, 18A, 18B, 18C, 19A, 19B, 19C, 20A, 20B, and 20C are views of intermediate processes in the manufacturing of a semiconductor device including nano-FETs, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Various embodiments provide a semiconductor device and methods of forming the same. For example, some embodiments provide a nano-FET that include protective layers between inner spacers and gate structures. The inner spacers may be between the protective layers and source/drain regions. The protective layers may be formed by a chemical reaction between sacrificial layers and plasma before the inner spacers are formed. As a result, the inner spacers and source/drain regions may be protected by the protective layers during etching processes, and sufficient electrical insulation between the source/drain regions and the gate structures may be provided by the protective layers and the inner spacers, which may reduce or eliminate parasitic capacitance between the source/drain regions and the gate structures. As a result, the performance and reliability of the semiconductor device may be improved.

Some embodiments discussed herein are described in the context of a semiconductor device including nano-FETs. However, various embodiments may be applied to dies including other types of transistors (e.g., fin field effect transistors (FinFETs), vertical field-effect transistors (VFETs), complementary field-effect transistors (CFETs), planar transistors, or the like) in lieu of or in combination with the nano-FETs.

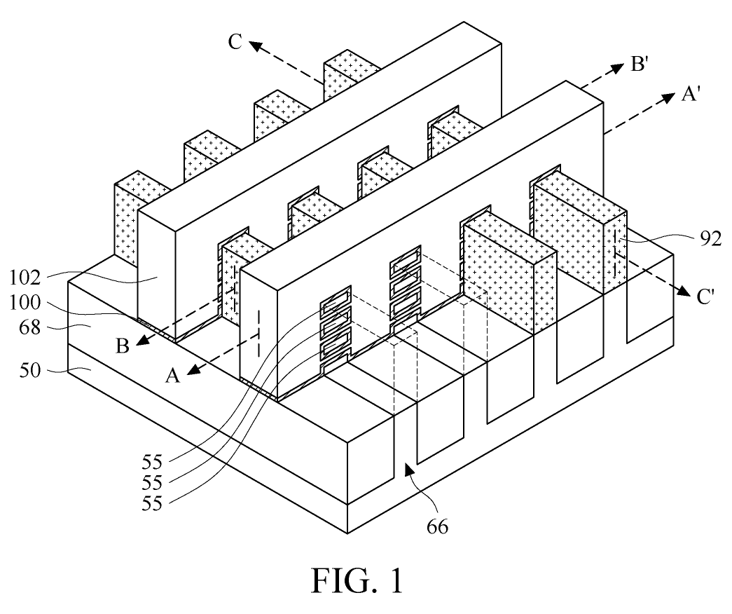

FIG. 1 illustrates an example of nano-FETs (e.g., nanowire FETs, nanosheet FETs, or the like) in a three-dimensional view. The nano-FETs comprise nanostructures 55 (e.g., nanosheets, nanowire, or the like) over fins 66 on a substrate 50 (e.g., a semiconductor substrate), wherein the nanostructures 55 act as channel regions for the nano-FETs. The nanostructure 55 may include p-type nanostructures, n-type nanostructures, or a combination thereof. Shallow trench isolation (STI) regions 68 are disposed between adjacent fins 66, which may protrude above and from between neighboring STI regions 68. Although the STI regions 68 are described/illustrated as being separate from the substrate 50, as used herein, the term “substrate” may refer to the semiconductor substrate alone or a combination of the semiconductor substrate and the STI regions. Additionally, although bottom portions of the fins 66 are illustrated as being single, continuous materials with the substrate 50, the bottom portions of the fins 66 and/or the substrate 50 may comprise a single material or a plurality of materials. In this context, the fins 66 refer to the portion extending between the neighboring STI regions 68. Gate dielectric layers 100 are over top surfaces of the fins 66 and along top surfaces, sidewalls, and bottom surfaces of the nanostructures 55. Gate electrodes 102 are over the gate dielectric layers 100. Epitaxial source/drain regions 92 are disposed on the fins 66 on opposing sides of the gate dielectric layers 100 and the gate electrodes 102.

FIG. 1 further illustrates reference cross-sections that are used in later figures. Reference cross-section A-A’ is along a longitudinal axis of a gate electrode 102 and in a direction, for example, perpendicular to the direction of current flow between the epitaxial source/drain regions 92 of a nano-FET. Reference cross-section B-B’ is parallel to the reference cross-section A-A’ and extends through epitaxial source/drain regions 92 of multiple nano-FETs. Reference cross-section C-C’ is perpendicular to the reference cross-section A-A’ and is parallel to a longitudinal axis of a fin 66 of the nano-FET and in a direction of, for example, a current flow between the epitaxial source/drain regions 92 of the nano-FET. Subsequent figures refer to these reference cross-sections for clarity. Some embodiments discussed herein are discussed in the context of nano-FETs formed using a gate-last process. In other embodiments, a gate-first process may be used. Also, some embodiments contemplate aspects used in planar devices, such as planar FETs or in FinFETs.

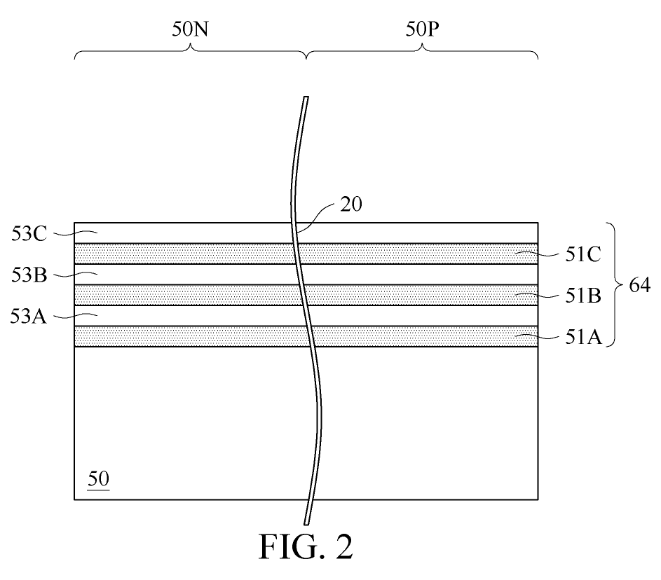

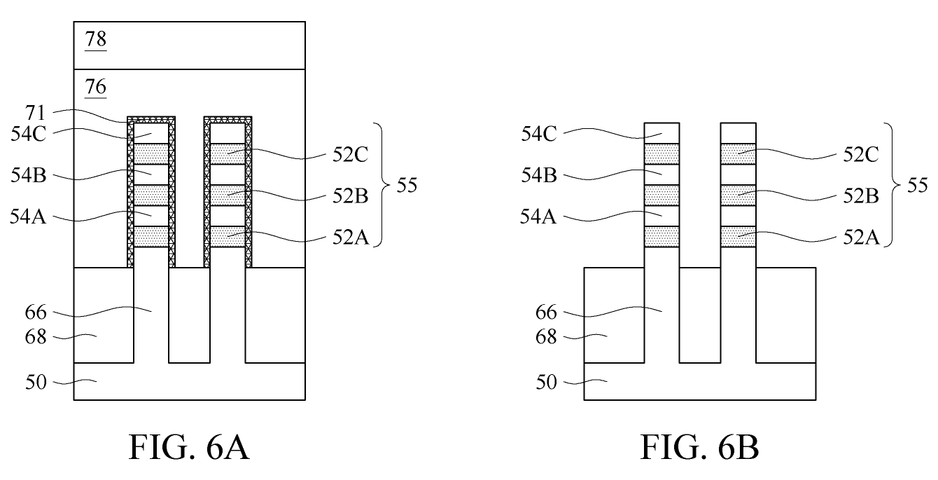

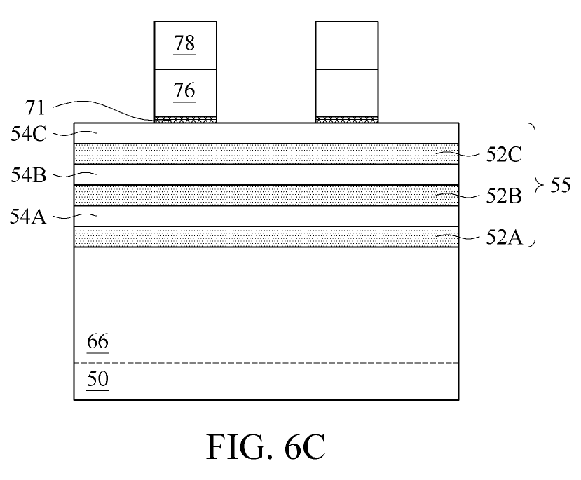

FIGS. 2-20C are views of intermediate processes in the manufacturing of a semiconductor device including nano-FET devices, in accordance with some embodiments. FIGS. 2, 3, 4, 5, 6A, 7A, 8A, 9A, 10A, 11A, 12A, 13A, 14A, 15A, 16A, 17A, 18A, 19A, and 20A illustrate cross-sectional views along the reference cross-section A-A’ illustrated in FIG. 1. FIGS. 6B, 7B, 8B, 9B, 10B, 11B, 12B, 12D, 13B, 14B, 15B, 16B, 17B, 18B, 19B, and 20B illustrate cross-sectional views along the reference cross-section B-B’ illustrated in FIG. 1. FIGS. 6C, 7C, 8C, 9C, 10C, 11C, 12C, 13C, 14C, 15C, 16C, 17C, 18C, 19C, and 20C illustrate cross-sectional views along the reference cross-section C-C’ illustrated in FIG. 1.

In FIG. 2, a substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

The substrate 50 has an n-type region 50N and a p-type region 50P. The n-type region 50N can be for forming n-type devices, such as NMOS transistors, e.g., n-type nano-FETs, and the p-type region 50P can be for forming p-type devices, such as PMOS transistors, e.g., p-type nano-FETs. The n-type region 50N may be physically separated from the p-type region 50P (as illustrated by divider 20), and any number of device features (e.g., other active devices, doped regions, isolation structures, etc.) may be disposed between the n-type region 50N and the p-type region 50P. Although one n-type region 50N and one p-type region 50P are illustrated, any number of n-type regions 50N and p-type regions 50P may be provided.

Further in FIG. 2, a multi-layer stack 64 is formed over the substrate 50. The multi-layer stack 64 includes alternating layers of first semiconductor layers 51A-51C (collectively referred to as first semiconductor layers 51) and second semiconductor layers 53A-53C (collectively referred to as second semiconductor layers 53). For purposes of illustration and as discussed in greater detail below, the first semiconductor layers 51 may be removed and the second semiconductor layers 53 may be patterned to form channel regions of nano-FETs in the n-type region 50N and the p-type region 50P. In some embodiments, the first semiconductor layers 51 are removed and the second semiconductor layers 53 are patterned to form channel regions of nano-FETs in the n-type region 50N, and the second semiconductor layers 53 are removed and the first semiconductor layers 51 are patterned to form channel regions of nano-FETs in the p-type region 50P. In some embodiments, the second semiconductor layers 53 are removed and the first semiconductor layers 51 are patterned to form channel regions of nano-FETs in the n-type region 50N, and the first semiconductor layers 51 are removed and the second semiconductor layers 53 are patterned to form channel regions of nano-FETs in the p-type region 50P. In some embodiments, the second semiconductor layers 53 are removed and the first semiconductor layers 51 are patterned to form channel regions of nano-FETs in both the n-type region 50N and the p-type region 50P.

The multi-layer stack 64 is illustrated as including three layers of each of the first semiconductor layers 51 and the second semiconductor layers 53 for illustrative purposes. In some embodiments, the multi-layer stack 64 may include any number of the first semiconductor layers 51 and the second semiconductor layers 53. Each of the layers of the multi-layer stack 64 may be epitaxially grown using a process such as chemical vapor deposition (CVD), atomic layer deposition (ALD), vapor phase epitaxy (VPE), molecular beam epitaxy (MBE), or the like. In various embodiments, the first semiconductor layers 51 may be formed of a first semiconductor material, such as silicon germanium or the like, and the second semiconductor layers 53 may be formed of a second semiconductor material different from the first semiconductor material, such as silicon or the like.

The first semiconductor materials and the second semiconductor materials may be materials having a high etching selectivity to one another. As such, the first semiconductor layers 51 of the first semiconductor material may be removed without significantly removing the second semiconductor layers 53 of the second semiconductor material thereby allowing the second semiconductor layers 53 to be patterned to form channel regions of nano-FETs. Similarly, in embodiments in which the second semiconductor layers 53 are removed and the first semiconductor layers 51 are patterned to form channel regions, the second semiconductor layers 53 of the second semiconductor material may be removed without significantly removing the first semiconductor layers 51 of the first semiconductor material, thereby allowing the first semiconductor layers 51 to be patterned to form channel regions of nano-FETs.

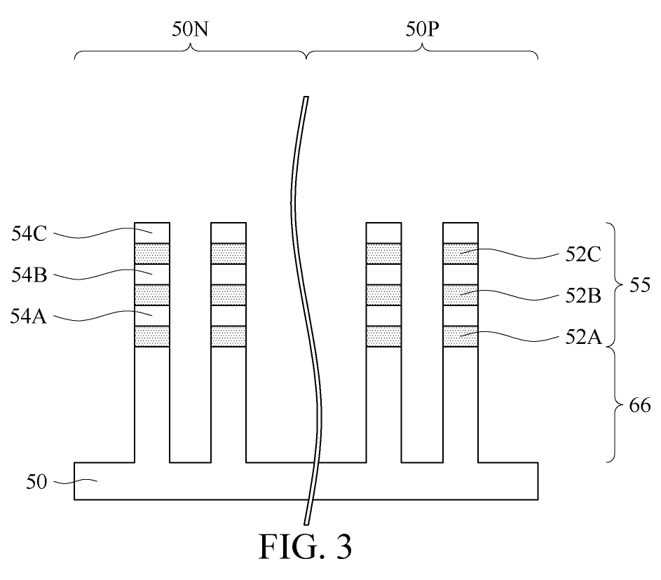

In FIG. 3, fins 66 are formed in the substrate 50 and nanostructures 55 are formed in the multi-layer stack 64, in accordance with some embodiments. The fins 66 may protrude from the substrate 50 and the fins 66 may be referred to as protrusions or protrusion structures. In some embodiments, the nanostructures 55 and the fins 66 may be formed in the multi-layer stack 64 and the substrate 50, respectively, by etching trenches in the multi-layer stack 64 and the substrate 50. The etching may be any acceptable etch process, such as a reactive ion etch (RIE), neutral beam etch (NBE), the like, or a combination thereof. The etching may be anisotropic. Forming the nanostructures 55 by etching the multi-layer stack 64 may further define first nanostructures 52A-52C (collectively referred to as the first nanostructures 52) from the first semiconductor layers 51 and define second nanostructures 54A-54C (collectively referred to as the second nanostructures 54) from the second semiconductor layers 53. The first nanostructures 52 and the second nanostructures 54 may be collectively referred to as nanostructures 55.

The fins 66 and the nanostructures 55 may be patterned by any suitable method. For example, the fins 66 and the nanostructures 55 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins 66.

FIG. 3 illustrates the fins 66 in the n-type region 50N and the p-type region 50P as having substantially equal widths for illustrative purposes. In some embodiments, widths of the fins 66 in the n-type region 50N may be greater or thinner than the fins 66 in the p-type region 50P. Further, while each of the fins 66 and the nanostructures 55 are illustrated as having a consistent width throughout, in other embodiments, the fins 66 and/or the nanostructures 55 may have tapered sidewalls such that a width of each of the fins 66 and/or the nanostructures 55 continuously increases in a direction towards the substrate 50. In such embodiments, each of the nanostructures 55 may have a different width and be trapezoidal in shape.

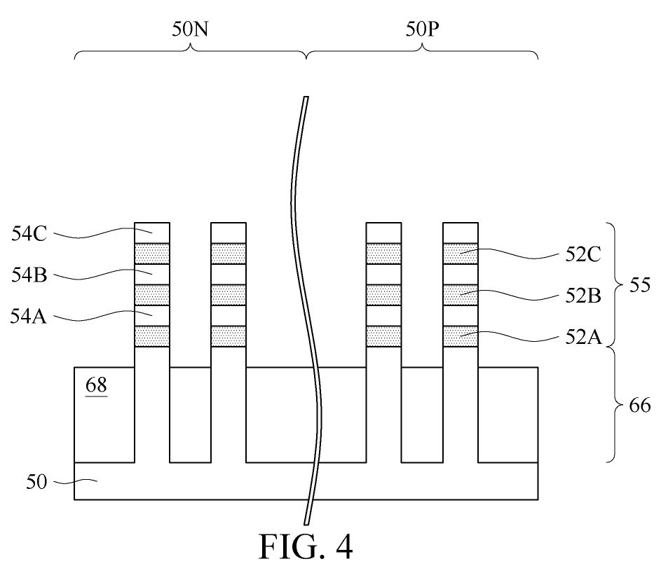

In FIG. 4, shallow trench isolation (STI) regions 68 are formed adjacent the fins 66. The STI regions 68 may be formed by depositing an insulation material over the substrate 50, the fins 66, and nanostructures 55, and between adjacent fins 66. The insulation material may be an oxide, such as silicon oxide, a nitride, such as silicon nitride, the like, or a combination thereof, and may be formed by high-density plasma CVD (HDP-CVD), flowable CVD (FCVD), the like, or a combination thereof. Other insulation materials formed by any acceptable process may be used. An anneal process may be performed once the insulation material is formed. Although the insulation material is illustrated as a single layer, some embodiments may utilize multiple layers.

A removal process may be then applied to the insulation material to remove excess insulation material over the nanostructures 55. In some embodiments, a planarization process such as a chemical mechanical polish (CMP), an etch-back process, combinations thereof, or the like may be utilized. The planarization process exposes the nanostructures 55 such that top surfaces of the nanostructures 55 and the insulation material may be substantially co-planar or level after the planarization process is complete. The insulation material may be then recessed to form the STI regions 68. The insulation material may be recessed such that upper portions of fins 66 in the n-type region 50N and the p-type region 50P protrude from between neighboring STI regions 68. The STI regions 68 may be recessed using an acceptable etching process, such as one that is selective to the material of the insulation material and etches the material of the insulation material at a faster rate than the material of the fins 66 and the nanostructures 55. For example, dilute hydrofluoric acid may be used when the insulation material is an oxide. After the removal process, the top surfaces of the STI regions 68 may have a flat surface as illustrated, a convex surface, a concave surface, or a combination thereof.

The process described above with respect to FIGS. 2-4 is one example of how the fins 66 and the nanostructures 55 may be formed. In some embodiments, the fins 66 and/or the nanostructures 55 may be formed using a mask and an epitaxial growth process. For example, a dielectric layer can be formed over a top surface of the substrate 50, and trenches can be etched through the dielectric layer to expose the underlying substrate 50. Epitaxial structures can be epitaxially grown in the trenches, and the dielectric layer can be recessed such that the epitaxial structures protrude from the dielectric layer to form the fins 66 and/or the nanostructures 55. The epitaxial structures may comprise the alternating semiconductor materials discussed above, such as the first semiconductor materials and the second semiconductor materials. In some embodiments where epitaxial structures are epitaxially grown, the epitaxially grown materials may be in situ doped during growth, which may obviate prior and/or subsequent implantations, although in situ and implantation doping may be used together.

Additionally, the first semiconductor layers 51 (and resulting first nanostructures 52) are illustrated and discussed herein as comprising the same materials in the p-type region 50P and the n-type region 50N, and the second semiconductor layers 53 (and resulting second nanostructures 54) are illustrated and discussed herein as comprising the same materials in the p-type region 50P and the n-type region 50N for illustrative purposes. In some embodiments, the first semiconductor layers 51 may comprise different materials in the p-type region 50P and the n-type region 50N. In some embodiments, the second semiconductor layers 53 may comprise different materials in the p-type region 50P and the n-type region 50N. In some embodiments, the first semiconductor layers 51 may comprise different materials in the p-type region 50P and the n-type region 50N, and the second semiconductor layers 53 may comprise different materials in the p-type region 50P and the n-type region 50N.

Further in FIG. 4, appropriate wells (not separately illustrated) may be formed in the fins 66, the nanostructures 55, and/or the STI regions 68. In embodiments with different well types, different implant steps for the n-type region 50N and the p-type region 50P may be achieved using a photoresist or other masks (not separately illustrated). For example, a photoresist may be formed over the fins 66 and the STI regions 68 in the n-type region 50N and the p-type region 50P. The photoresist is patterned to expose the p-type region 50P. The photoresist can be formed by using a spin-on technique and can be patterned using acceptable photolithography techniques. Once the photoresist is patterned, an n-type impurity implant is performed in the p-type region 50P, and the photoresist may act as a mask to substantially prevent n-type impurities from being implanted into the n-type region 50N. The n-type impurities may be phosphorus, arsenic, antimony, or the like implanted in the region to a concentration in a range from about 10¹³ atoms/cm³ to about 10¹⁴ atoms/cm³. After the implant, the photoresist is removed, such as by an acceptable ashing process.

Following or prior to the implanting of the p-type region 50P, a photoresist or other masks (not separately illustrated) is formed over the fins 66, the nanostructures 55, and the STI regions 68 in the p-type region 50P and the n-type region 50N. The photoresist is patterned to expose the n-type region 50N. The photoresist can be formed by using a spin-on technique and can be patterned using acceptable photolithography techniques. Once the photoresist is patterned, a p-type impurity implant may be performed in the n-type region 50N, and the photoresist may act as a mask to substantially prevent p-type impurities from being implanted into the p-type region 50P. The p-type impurities may be boron, boron fluoride, indium, or the like implanted in the region to a concentration in a range from about 10¹³ atoms/cm³ to about 10¹⁴ atoms/cm³. After the implantation, the photoresist may be removed, such as by an acceptable ashing process. After the implantations of the n-type region 50N and the p-type region 50P, an annealing may be performed to repair implant damage and to activate the p-type and/or n-type impurities that were implanted. In some embodiments, the grown materials of epitaxial fins may be in situ doped during growth, which may obviate the implantations, although in situ and implantation doping may be used together.

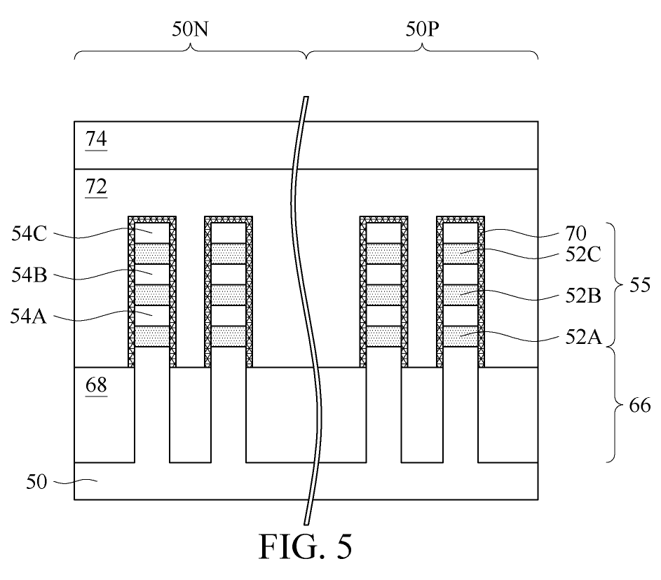

In FIG. 5, a dummy dielectric layer 70 is formed on the fins 66 and/or the nanostructures 55. The dummy dielectric layer 70 may be, for example, silicon oxide, silicon nitride, a combination thereof, or the like, and may be deposited or thermally grown according to acceptable techniques. A dummy gate layer 72 is formed over the dummy dielectric layer 70, and a mask layer 74 is formed over the dummy gate layer 72. The dummy gate layer 72 may be deposited over the dummy dielectric layer 70 and then planarized, such as by a CMP. The mask layer 74 may be deposited over the dummy gate layer 72. The dummy gate layer 72 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer 72 may be deposited by physical vapor deposition (PVD), CVD, sputter deposition, or other techniques for depositing the selected material. The dummy gate layer 72 may be made of other materials that have a high etching selectivity to the etching of isolation regions. The mask layer 74 may include, for example, silicon nitride, silicon oxynitride, or the like. In this example, a single dummy gate layer 72 and a single mask layer 74 are formed across the n-type region 50N and the p-type region 50P. It is noted that the dummy dielectric layer 70 is shown covering only the fins 66 and the nanostructures 55 for illustrative purposes. In some embodiments, the dummy dielectric layer 70 may be deposited such that the dummy dielectric layer 70 covers the STI regions 68, such that the dummy dielectric layer 70 extends between the dummy gate layer 72 and the STI regions 68.

FIGS. 6A-20C illustrate various additional processes in the manufacturing of the nano-FET devices, in accordance to some embodiments. FIGS. 6A-20C illustrate features in either or both the n-type region 50N or the p-type region 50P. In FIGS. 6A-6C, masks 78, dummy gates 76, and dummy gate dielectrics 71 are formed. The dummy gates 76 and dummy gate dielectrics 71 may be collectively referred to as dummy gate structures. The mask layer 74 (see FIG. 5) may be patterned using suitable photolithography and etching processes to form the masks 78. The pattern of the masks 78 then may be transferred to the dummy gate layer 72 and to the dummy dielectric layer 70 to form the dummy gates 76 and the dummy gate dielectrics 71, respectively, using suitable etching processes. The dummy gates 76 cover respective channel regions of the fins 66 and the overlying respective nanostructures 55. The pattern of the masks 78 may be used to separate each of the dummy gates 76 from adjacent dummy gates 76. The dummy gates 76 may also have a lengthwise direction substantially perpendicular to the lengthwise direction of respective fins 66.

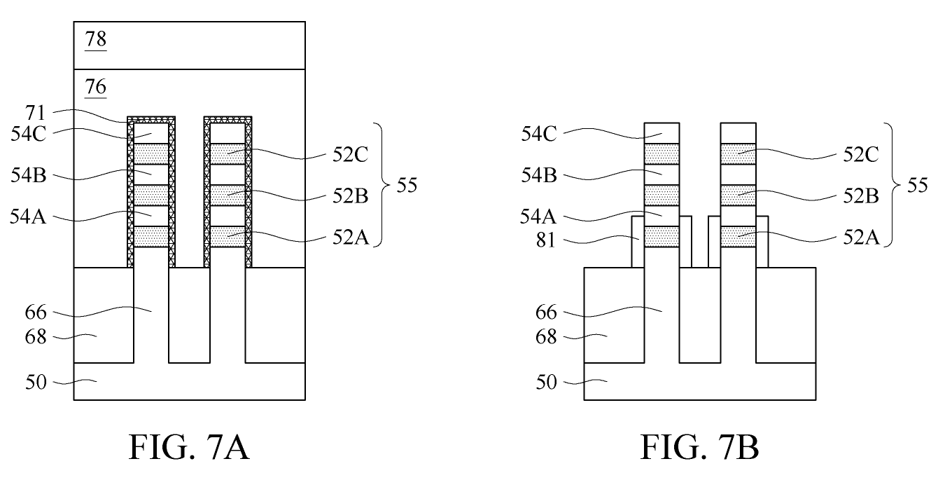

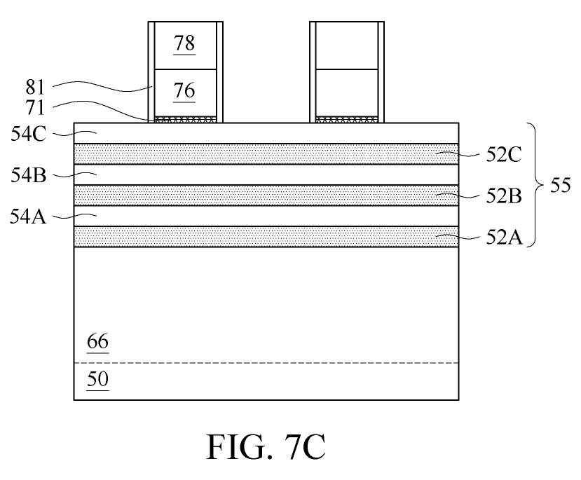

In FIGS. 7A-7C, spacers 81 are formed. The spacers 81 may self-align subsequently formed source/drain regions, as well as protect the dummy gate dielectrics 71 and the dummy gate 76 during subsequent etching processes. The spacers 81 may be a single layer of one material or multiple sub-layers of different materials with different etch rates. In some embodiments, the spacers 81 comprise two sub-layers with different materials of different etch rates, which may be selected from silicon oxide, silicon nitride, silicon oxynitride, or the like. The spacers 81 may be formed by forming a spacer layer by thermal oxidation or a suitable deposition process, such as CVD, ALD, or the like, and then patterning the spacer layer by a suitable etching process, such as an isotropic etching process (e.g., a wet etching process), an anisotropic etching process (e.g., a dry etching process), or the like. The spacer layer may be formed on top surfaces of the STI regions 68; top surfaces and sidewalls of the fins 66, the nanostructures 55, and the masks 78; and sidewalls of the dummy gates 76 and the dummy gate dielectrics 71. After the etching process, the spacers 81 may remain on sidewalls of the fins 66 and/or nanostructures 55 as illustrated in FIG. 7B; and sidewalls of the masks 78, the dummy gates 76, and the dummy gate dielectrics 71 as illustrated in FIG. 7C.

In the embodiments in which the spacers 81 comprise two sublayers with different materials, after the first sublayer is formed and prior to forming the second sublayer, implants for lightly-doped source/drain (LDD) regions (not separately illustrated) may be performed. Similar to the implants discussed above in FIG. 4, a mask, such as a photoresist, may be formed over the n-type region 50N, while exposing the p-type region 50P, and appropriate type (e.g., p-type) impurities may be implanted into the exposed fins 66 and nanostructures 55 in the p-type region 50P. The mask may then be removed. Subsequently, a mask, such as a photoresist, may be formed over the p-type region 50P while exposing the n-type region 50N, and appropriate type impurities (e.g., n-type) may be implanted into the exposed fins 66 and nanostructures 55 in the n-type region 50N. The mask may then be removed. The n-type impurities may be the any of the n-type impurities previously discussed, and the p-type impurities may be the any of the p-type impurities previously discussed. The lightly-doped source/drain regions may have a concentration of impurities in a range from about 1x10¹⁵ atoms/cm³ to about 1x10¹⁹ atoms/cm³. An annealing may be used to repair implant damage and to activate the implanted impurities.

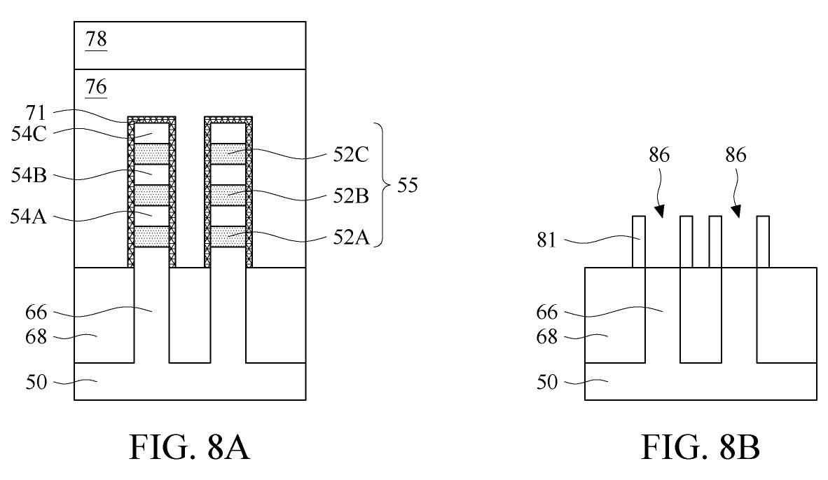

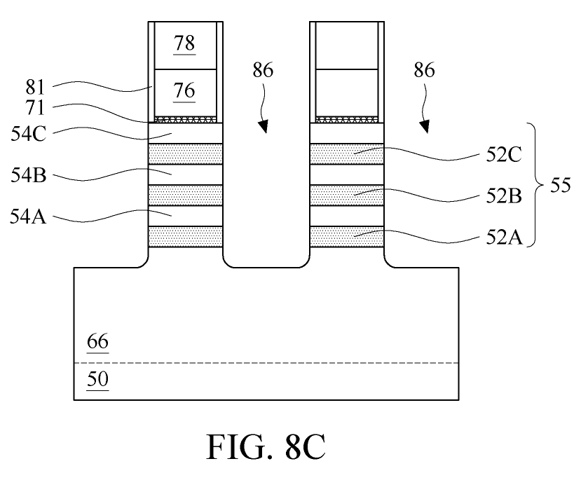

In FIGS. 8A-8C, first recesses 86 are formed in the fins 66 and the nanostructures 55. The first recesses 86 may extend through the first nanostructures 52 and the second nanostructures 54, and into the fins 66. As illustrated in FIG. 8B, top surfaces of the STI regions 68 (e.g., top surfaces of the fins 66) may be level with bottom surfaces of the first recesses 86. In some embodiments, the bottom surfaces of the first recesses 86 are disposed below the top surfaces of the STI regions 68. The first recesses 86 may be formed by etching the fins 66, the nanostructures 55, and the substrate 50 using anisotropic etching processes, such as RIE, NBE, or the like. The spacers 81 and the masks 78 may mask portions of the fins 66, the nanostructures 55, and the substrate 50 during the etching processes used to form the first recesses 86. A single etch process or multiple etch processes may be used to etch each layer of the nanostructures 55 and/or the fins 66. Timed etch processes may be used to stop the etching after the first recesses 86 reach desired depths.

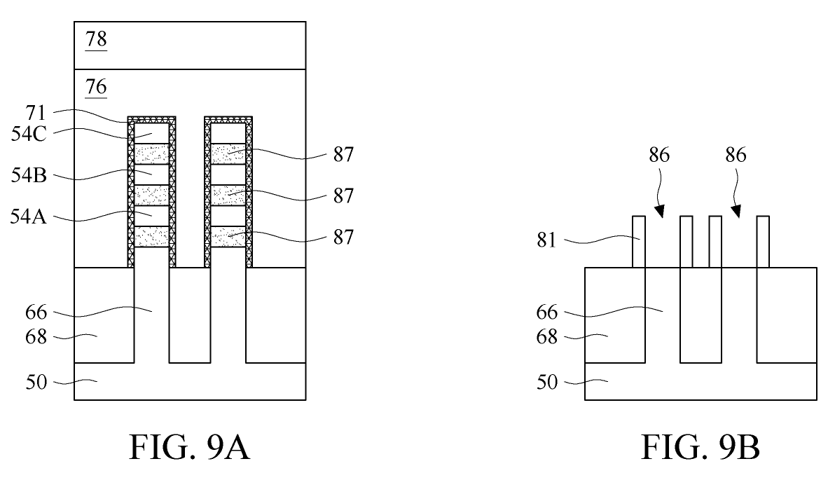

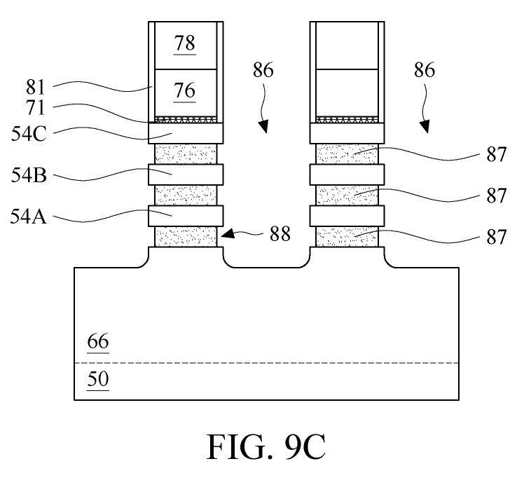

In FIGS. 9A-9C, the first nanostructures 52 are replaced with sacrificial layers 87. Replacing the first nanostructures 52 with the sacrificial layers 87 may prevent reduce or prevent defects from forming on surfaces of the second nanostructures 54 adjacent the first nanostructures 52 during subsequent annealing processes. Replacing the first nanostructures 52 may include first removing the first nanostructures 52 using a suitable etching process, such as an isotropic etch process, performed through the first recesses 86. The etching process may selectively remove the material of the first nanostructures 52 without significantly removing materials of the second nanostructures 54 or the semiconductor fins 66. In the embodiments in which the first nanostructures 52 comprise silicon germanium and the second nanostructures 54 include silicon, an etching process with tetramethylammonium hydroxide (TMAH), ammonium hydroxide (NH₄OH), or the like are used to remove the first nanostructures 52.

Subsequently, the sacrificial layers 87 may be deposited in spaces where the first nanostructures 52 occupied before being removed. The sacrificial layers 87 may be deposited by a suitable deposition process, such as CVD, ALD, or the like. The sacrificial layers 87 layer may comprise an insulating material, such as silicon oxide, or the like. The sacrificial layers 87 may then be partially removed by an etching process to form second recesses 88, after which sidewalls of the sacrificial layers 87 are recessed from sidewalls of the second nanostructures 54. The etching process may selectively remove the material of the sacrificial layers 87 without significantly removing materials of the second nanostructures 54 or the semiconductor fins 66. The etching process may be isotropic or anisotropic. In some embodiments, the sacrificial layers 87 may be etched by a wet etching process using dilute HF, or the like. The sidewalls of sacrificial layers 87 are illustrated as being straight in FIG. 9C as an example, the sidewalls of the sacrificial layers 87 may be concave or convex in some embodiments.

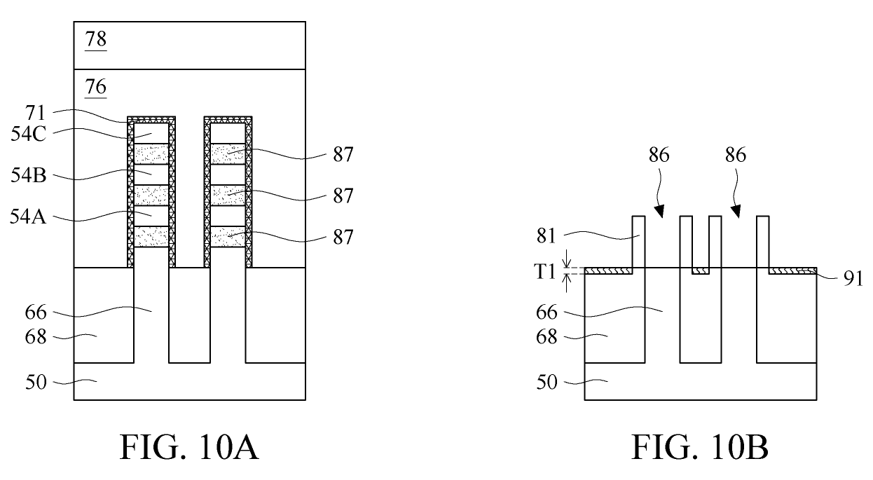

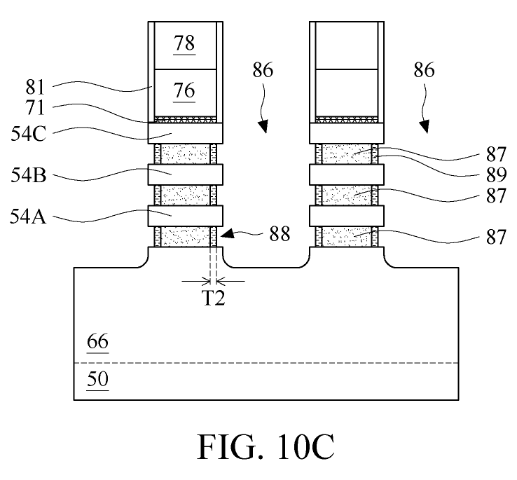

In FIGS. 10A-10C, protective layers 89 are formed on the sidewalls of the sacrificial layers 87 and dielectric layers 91 are formed on exposed surfaces of the STI regions 68. The protective layers 89 may protect subsequently formed inner spacers and subsequently formed source/drain regions during subsequent etching processes that may remove the sacrificial layers 87 as described in greater details below. The protective layers 89 may comprise a dielectric material with a high etching selectivity to the material of the sacrificial layers 87, such as silicon oxynitride or the like. The material of the protective layers 89 may have a dielectric constant (k) in a range from about 5 to about 7, which may lead to sufficient electrical insulation between the subsequently formed source/drain regions and subsequently formed gate structures as described in greater details below.

The protective layers 89 may be formed by exposing the structure shown in FIGS. 10A-10C to a plasma and converting portions of the sacrificial layers 87 adjacent the sidewalls of the sacrificial layers 87 to the protective layers 89 by the chemical reaction. During the chemical reaction, the radicals in the plasma may react with the material of the sacrificial layers 87 to yield the material of the protective layers 89. In some embodiments, the material of the sacrificial layers 87 is silicon oxide, and ammonia plasma is used for the chemical reaction, during which nitrogen radicals react with silicon oxide to yield silicon oxynitride as the material of the protective layers 89. During the chemical reaction, the radicals in the plasma may also react with the STI regions 68 and covert portions of the STI regions 68 adjacent the exposed surfaces of the STI regions 68 to the dielectric layers 91. In some embodiments, the material of the STI regions 68 is silicon oxide and ammonia plasma is used for the chemical reaction, during which nitrogen radicals react with silicon oxide to yield silicon oxynitride as the material of the dielectric layers 91. In some embodiments, the protective layers 89 and the dielectric layers 91 comprise a same material.

After the chemical reaction, the protective layers 89 may have shapes of linear strips and fully cover sidewalls of remaining portions (e.g., unconverted portions) of the sacrificial layers 87 while leaving portions of top surfaces and bottom surfaces of the second nanostructures 54 exposed. The protective layers 89 may have the thickness T2 in a range from about 2 nm to about 3 nm. Such shapes, sizes, and locations of the protective layers 89 may result in sufficient protection of the subsequently formed inner spacers and the subsequently formed source/drain regions during the subsequent etching process as well as sufficient electrical insulation between the subsequently formed source/drain regions and the subsequently formed gate structures as described in greater details below. Bottom surfaces of the dielectric layers 91 may be below top surfaces of the fins 66 and the STI regions 68. The dielectric layers 91 may have a thickness T1 in a range from about 1 nm to about 2 nm. In some embodiments, the thickness T2 is larger than the thickness T1, which is due to that the material of the STI regions 68 has a higher density than the material of the sacrificial layers 87.

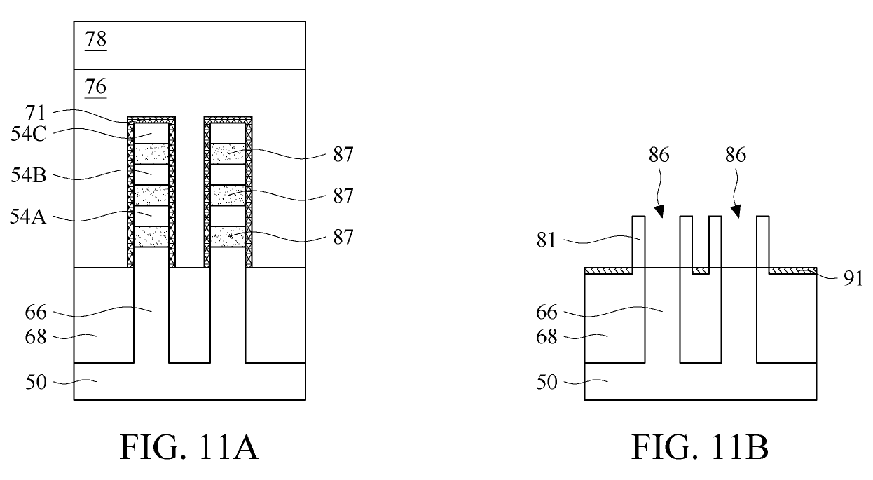

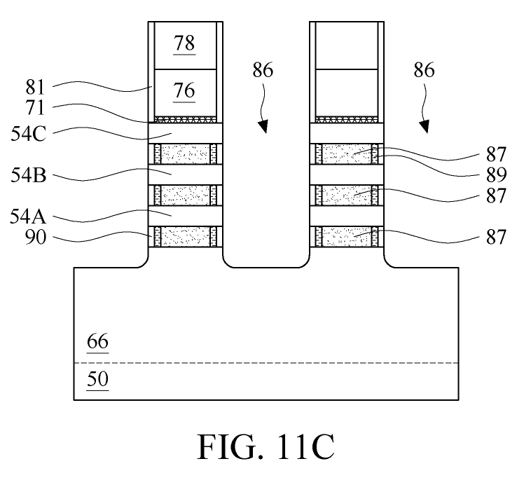

In FIGS. 11A-11C, inner spacers 90 are formed in the second recesses 88. The inner spacers 90 and the protective layers 89 together may also provide electrical insulation between the subsequently formed source/drain regions and the subsequently formed gate structures as discussed in greater details below. The inner spacers 90 may extend along sidewalls of the protective layers 89 and be in contact with the portions of the top surfaces and the bottom surfaces of the second nanostructures 54 previously exposed after the protective layers 89 are formed and before the inner spacers 90 are formed. The inner spacers 90 may be separated from the sacrificial layers 87 by the protective layers 89. Such shapes, sizes, and locations of the inner spacers 90 may be at least partially due to the shapes, sizes, and locations of the protective layers 89 mentioned above, and may lead to sufficient electrical insulation between the subsequently formed source/drain regions and the subsequently formed gate structures.

The inner spacers 90 may be formed by depositing an inner spacer layer (not separately illustrated) over the structure shown in FIGS. 10A-10C, and then etching the inner spacer layer. The inner spacer layer may be deposited by a suitable deposition process, such as CVD, ALD, or the like. The inner spacer layer may comprise a dielectric material, such as silicon nitride or the like. The material of inner spacer layer may have a dielectric constant (k) less than about 3.5, which may be lower than the dielectric constant (k) of the protective layers 89. The inner spacer layer may comprise a material different from the material of the protective layers 89. The inner spacer layer may be etched to form the inner spacers 90 by an anisotropic etching process, such as RIE, NBE, or the like. Outer sidewalls of the inner spacers 90 are illustrated in FIG. 11C as being flush with sidewalls of the second nanostructures 54 as an example, the outer sidewalls of the inner spacers 90 may extend beyond or be recessed from sidewalls of the second nanostructures 54 in some embodiments.

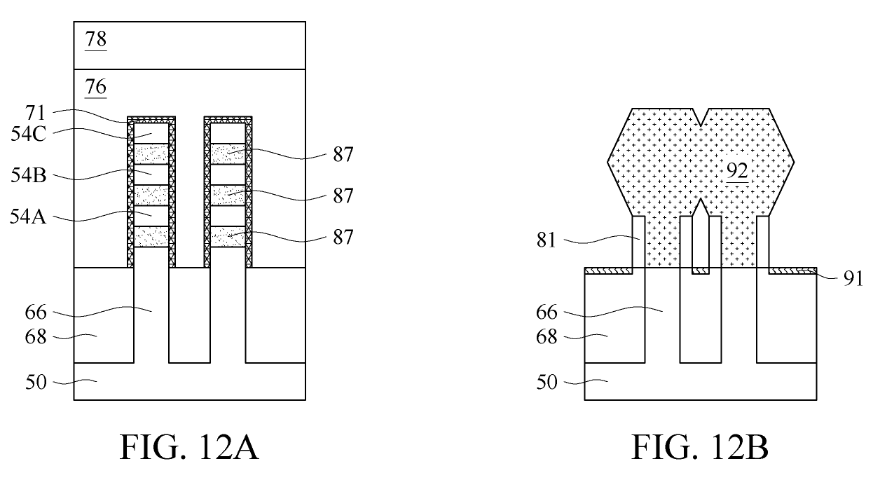

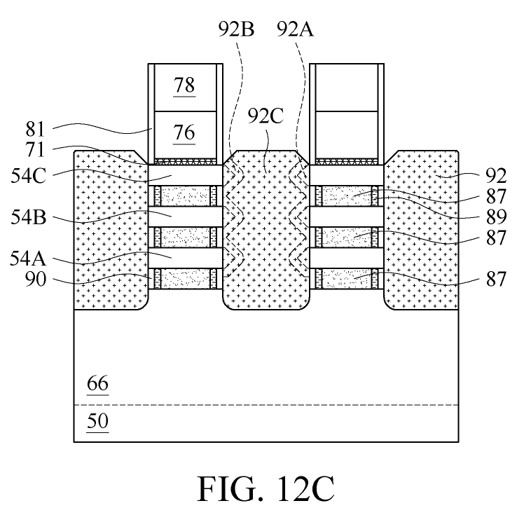

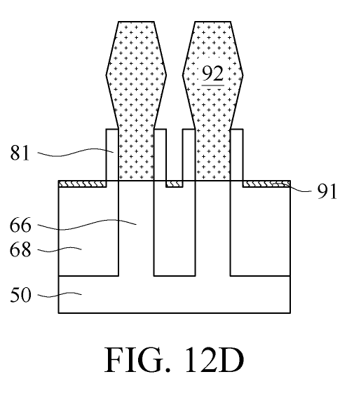

In FIGS. 12A-12C, epitaxial source/drain regions 92 are formed in the first recesses 86. In some embodiments, the epitaxial source/drain regions 92 may exert stress on the second nanostructures 54, thereby improving performance. As illustrated in FIG. 12C, the epitaxial source/drain regions 92 are formed in the first recesses 86 such that each dummy gate 76 is disposed between respective neighboring pairs of the epitaxial source/drain regions 92. The protective layers 89 may be separated from the epitaxial source/drain regions 92 by the inner spacers 90.

The epitaxial source/drain regions 92 in the n-type region 50N, e.g., the NMOS region, may be formed by masking the p-type region 50P, e.g., the PMOS region. Then, the epitaxial source/drain regions 92 are epitaxially grown in the first recesses 86 in the n-type region 50N. The epitaxial source/drain regions 92 may include any acceptable material appropriate for n-type nano-FETs. For example, if the second nanostructures 54 are silicon, the epitaxial source/drain regions 92 may include materials exerting a tensile strain on the second nanostructures 54, such as silicon, silicon carbide, phosphorous doped silicon carbide, silicon phosphide, or the like. The epitaxial source/drain regions 92 may have surfaces raised from respective upper surfaces of the nanostructures 55 and may have facets.

The epitaxial source/drain regions 92 in the p-type region 50P, e.g., the PMOS region, may be formed by masking the n-type region 50N, e.g., the NMOS region. Then, the epitaxial source/drain regions 92 are epitaxially grown in the first recesses 86 in the p-type region 50P. The epitaxial source/drain regions 92 may include any acceptable material appropriate for p-type nano-FETs. For example, if the second nanostructures 54 are silicon, the epitaxial source/drain regions 92 may comprise materials exerting a compressive strain on the second nanostructures 54, such as silicon-germanium, boron doped silicon-germanium, germanium, germanium tin, or the like. The epitaxial source/drain regions 92 may have surfaces raised from respective surfaces of the nanostructures 55 and may have facets.

The epitaxial source/drain regions 92, the sacrificial layers 87, the second nanostructures 54, and/or the substrate 50 may be implanted with dopants to form source/drain regions, similar to the process previously discussed for forming lightly-doped source/drain regions, followed by an annealing process. The source/drain regions may have an impurity concentration of between about 1x10¹⁹ atoms/cm³ and about 1x10²¹ atoms/cm³. The n-type and/or p-type impurities for source/drain regions may be any of the impurities previously discussed. In some embodiments, the epitaxial source/drain regions 92 may be in situ doped during growth.

As a result of the epitaxy processes used to form the epitaxial source/drain regions 92 in the n-type region 50N and the p-type region 50P, upper surfaces of the epitaxial source/drain regions 92 may have facets which expand laterally outward beyond sidewalls of the nanostructures 55. In some embodiments, these facets cause adjacent epitaxial source/drain regions 92 of a same nano-FET to merge as illustrated by FIG. 12B. In some embodiments, adjacent epitaxial source/drain regions 92 remain separated after the epitaxy process is completed as illustrated by FIG. 12D.

The epitaxial source/drain regions 92 may comprise one or more semiconductor material layers. In some embodiments, the epitaxial source/drain regions 92 comprise first liner layers 92A on the sidewalls of the second nanostructures 54, second liner layers 92B on the first liner layers 92A, and fill layers 92C on the second liner layers 92B, as shown in FIG. 12C. The first liner layers 92A, the second liner layers 92B, and the fill layers 92C may be formed of different semiconductor materials and/or may be doped to different dopant concentrations. The first liner layers 92A may be grown first, the second liner layers 92B may be grown on the first liner layers 92A, and the fill layers 92C may be grown on the second liner layers 92B.

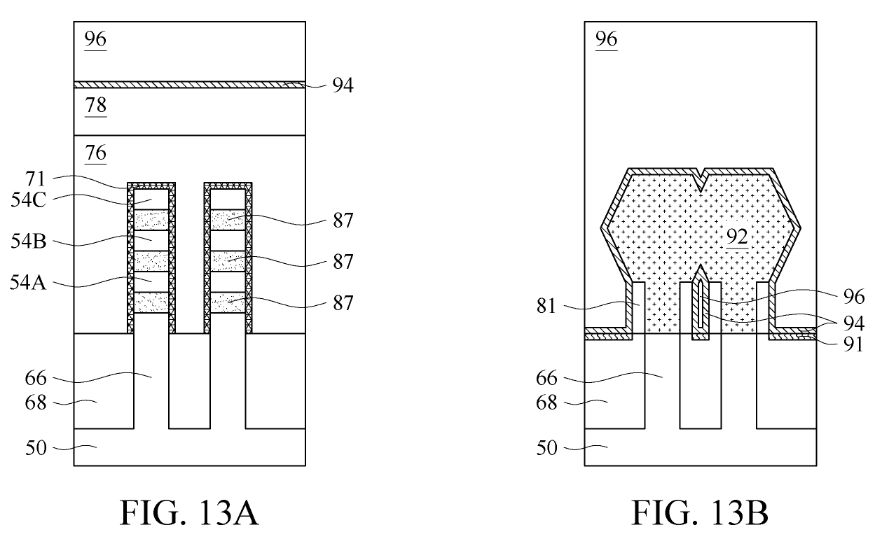

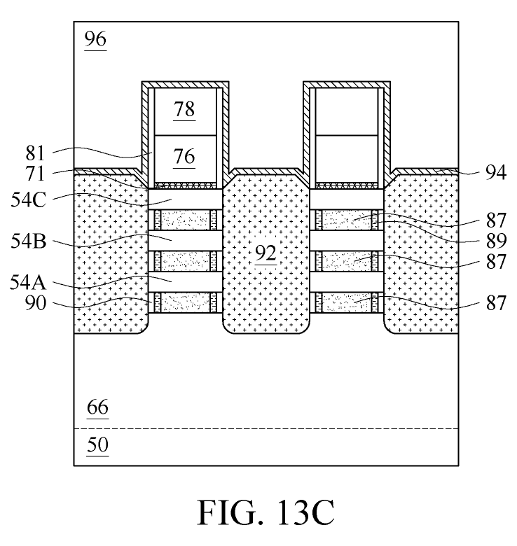

In FIGS. 13A-13C, a first interlayer dielectric (ILD) 96 is deposited over the structure illustrated in FIGS. 12A-12C. The first ILD 96 may be formed of a dielectric material, and may be deposited by any suitable method, such as CVD, plasma-enhanced CVD (PECVD), or FCVD. Dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used. In some embodiments, a contact etch stop layer (CESL) 94 is disposed between the first ILD 96 and the epitaxial source/drain regions 92, the masks 78, the spacers 81, and the dielectric layers 91. The CESL 94 may comprise a dielectric material, such as, silicon nitride, silicon oxide, silicon oxynitride, or the like, having a different etch rate than the material of the overlying first ILD 96. In some embodiments, the dielectric layers 91 comprise a different material from the CESL 94.

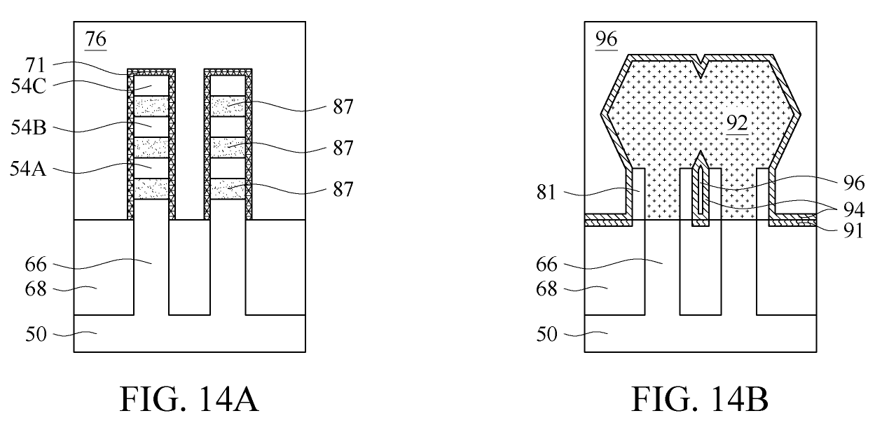

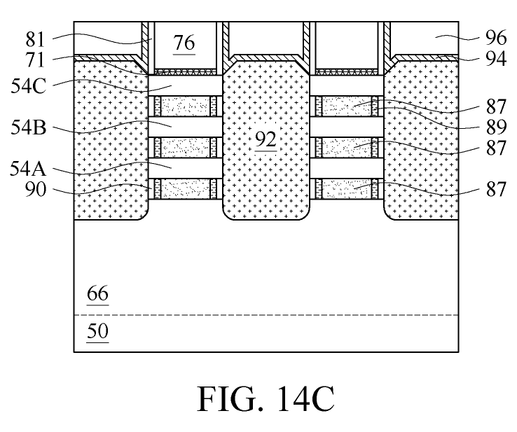

In FIGS. 14A-14C, a planarization process, such as CMP, may be performed to level the top surface of the first ILD 96 with the top surfaces of the dummy gates 76 or the masks 78. The planarization process may also remove the masks 78 on the dummy gates 76, and portions of the spacers 81 along sidewalls of the masks 78. After the planarization process, top surfaces of the dummy gates 76, the spacers 81, and the first ILD 96 are level within process variations. Accordingly, the top surfaces of the dummy gates 76 are exposed through the first ILD 96. In some embodiments, the masks 78 may remain, in which case the planarization process levels the top surface of the first ILD 96 with top surface of the masks 78 and the spacers 81.

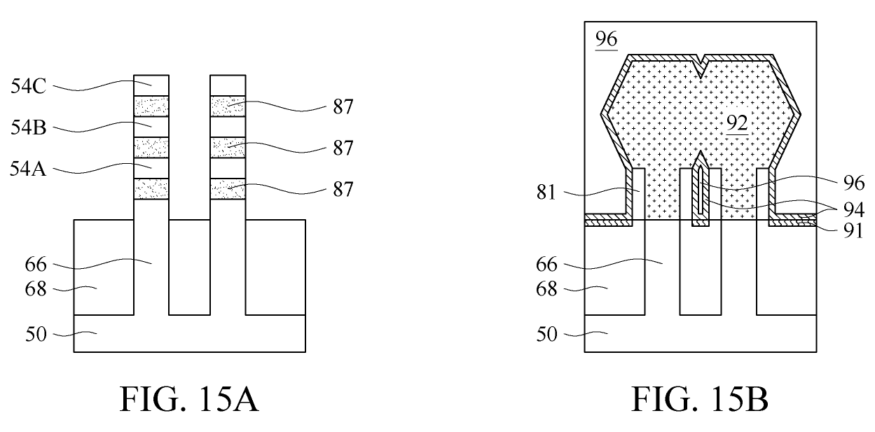

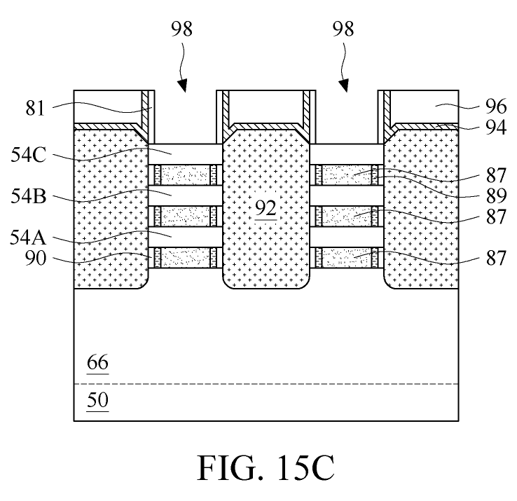

In FIGS. 15A-15C, the dummy gates 76 and the dummy gate dielectrics 71 are removed in one or more etching processes to form third recesses 98. In some embodiments, the dummy gates 76 and the dummy gate dielectrics 71 are removed by an anisotropic dry etch process. For example, the etching processes may include dry etching processes using reaction gas(es) that selectively etch the dummy gates 76 and the dummy gate dielectrics 71 at faster rates than the first ILD 96 and/or the spacers 81. Each of the third recess 98 exposes and/or overlies portions of nanostructures 55, which act as channel regions in subsequently completed nano-FETs. Portions of the nanostructures 55, which may act as the channel regions, are disposed between neighboring pairs of the epitaxial source/drain regions 92. During the etching processes, the dummy gate dielectrics 71 may be used as etch stop layers when the dummy gates 76 are removed and may be removed after the removal of the dummy gates 76.

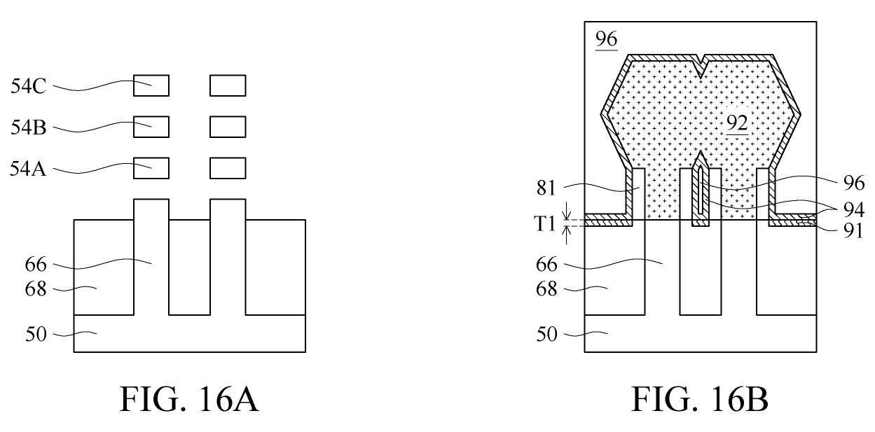

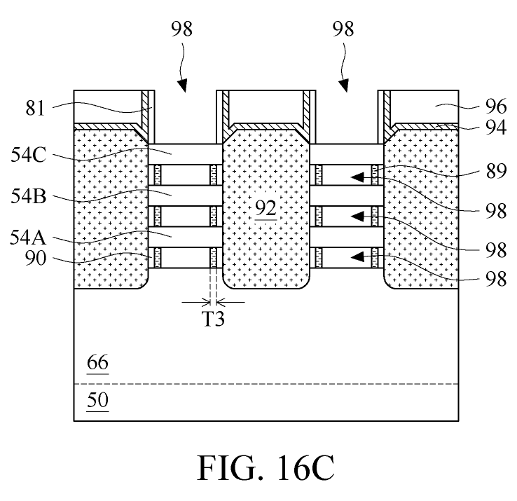

In FIGS. 16A-16C, the sacrificial layers 87 are removed, which extends the third recesses 98. The sacrificial layers 87 may be removed by performing an isotropic etching process, such as wet etching or the like, using etchants which may selectively remove the materials of the sacrificial layers 87, while the second nanostructures 54, the substrate 50, the STI regions 68 may be at most slightly etched. The protective layers 89 may protect the inner spacers 90 and the epitaxial source/drain regions 92 during the etching process, so that the inner spacers 90 and the epitaxial source/drain regions 92 may remain unetched. The protective layers 89 may be also at most slightly etched. After the etching process, the protective layers 89 may have the thickness T3 in a range from about 1 nm to about 2 nm. In some embodiments, the thickness T2 is larger than the thickness T3. In the embodiments in which the sacrificial layers 87 comprise silicon germanium and the second nanostructures 54 include silicon, an etching process with tetramethylammonium hydroxide (TMAH), ammonium hydroxide (NH₄OH), or the like are used to remove the sacrificial layers 87.

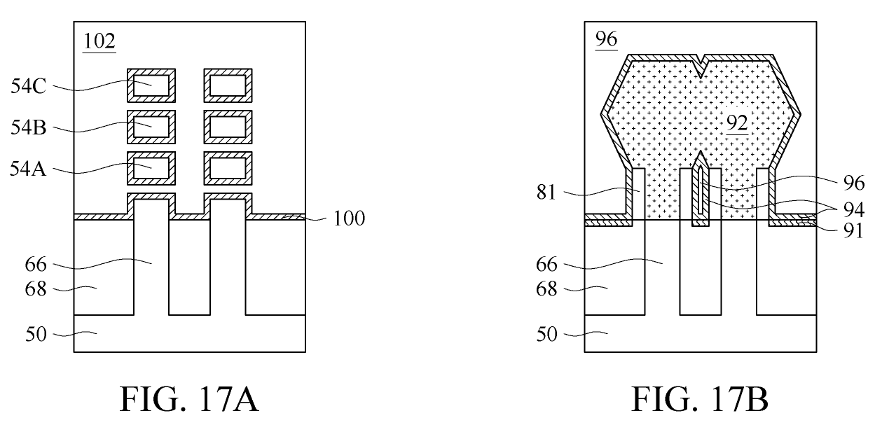

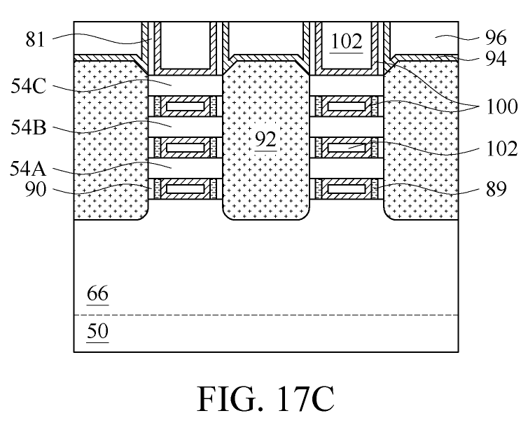

In FIGS. 17A-17C, gate dielectric layers 100 and gate electrodes 102 are formed in the third recesses 98. The gate dielectric layers 100 may be deposited conformally in the third recesses 98. The gate dielectric layers 100 may be formed on top surfaces and sidewalls of the substrate 50 and on top surfaces, sidewalls, and bottom surfaces of the second nanostructures 54. The gate dielectric layers 100 may also be deposited on top surfaces of the first ILD 96, the CESL 94, the spacers 81, and the STI regions 68 as well as on sidewalls of the spacers 81 and the protective layers 89.

In some embodiments, the gate dielectric layers 100 comprise one or more dielectric layers, such as an oxide, a metal oxide, the like, or combinations thereof. For example, in some embodiments, the gate dielectrics may comprise a silicon oxide layer and a metal oxide layer over the silicon oxide layer. In some embodiments, the gate dielectric layers 100 include a high-k dielectric material, and in these embodiments, the gate dielectric layers 100 may have a dielectric constant (k) value greater than about 7.0, and may include a metal oxide or a silicate of hafnium, aluminum, zirconium, lanthanum, manganese, barium, titanium, lead, and combinations thereof. The structure of the gate dielectric layers 100 may be the same or different in the n-type region 50N and the p-type region 50P. The formation methods of the gate dielectric layers 100 may include molecular-beam deposition (MBD), ALD, PECVD, or the like.

The gate electrodes 102 are deposited over the gate dielectric layers 100, respectively, and fill the remaining portions of the third recesses 98. The gate electrodes 102 may include a metal-containing material such as titanium nitride, titanium oxide, tantalum nitride, tantalum carbide, cobalt, ruthenium, aluminum, tungsten, combinations thereof, or multi-layers thereof. For example, although single layer gate electrodes 102 are illustrated in FIGS. 17A and 17C, the gate electrodes 102 may comprise any number of liner layers, any number of work function tuning layers, and a fill material. Any combination of the layers which make up the gate electrodes 102 may be deposited between adjacent ones of the second nanostructures 54 and between the second nanostructure 54A and the substrate 50.

The formation of the gate dielectric layers 100 in the n-type region 50N and the p-type region 50P may occur simultaneously such that the gate dielectric layers 100 in each region are formed from the same materials, and the formation of the gate electrodes 102 may occur simultaneously such that the gate electrodes 102 in each region are formed from the same materials. In some embodiments, the gate dielectric layers 100 in each region may be formed by distinct processes, such that the gate dielectric layers 100 may be different materials and/or have a different number of layers, and/or the gate electrodes 102 in each region may be formed by distinct processes, such that the gate electrodes 102 may be different materials and/or have a different number of layers. Various masking steps may be used to mask and expose appropriate regions when using distinct processes.

After the filling of the third recesses 98, a planarization process, such as CMP, may be performed to remove the excess portions of the gate dielectric layers 100 and the material of the gate electrodes 102, which excess portions are over the top surface of the first ILD 96. The remaining portions of material of the gate electrodes 102 and the gate dielectric layers 100 thus form replacement gate structures of the resulting nano-FETs. The gate electrodes 102 and the gate dielectric layers 100 may be collectively referred to as gate structures. The inner spacers 90 and the protective layers 89 may separate epitaxial source/drain regions 92 from the gate structures and provide sufficient electrical insulation between the epitaxial source/drain regions 92 and the gate structures. As a result, parasitic capacitance between the epitaxial source/drain regions 92 and the gate structures may be reduced or eliminated, thereby improving the performance and reliability of the subsequently formed semiconductor device.

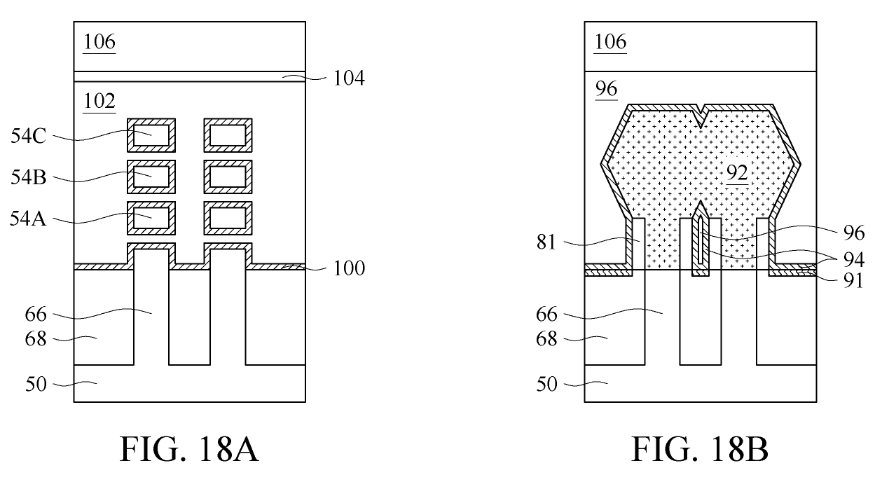

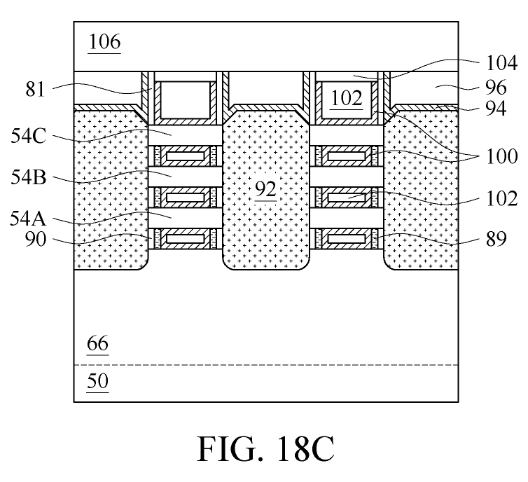

In FIGS. 18A-18C, the gate structures (including the gate dielectric layers 100 and the corresponding overlying gate electrodes 102) are recessed, gate masks 104 are formed in the recesses, and a second ILD 106 is formed over the first ILD 96 and the gate masks 104. The recesses may be formed directly over the gate structures and between opposing portions of spacers 81. Gate masks 104 may comprise one or more layers of dielectric material, such as silicon nitride, silicon oxynitride, or the like. A planarization process may be performed to remove excess material of the gate masks 104. The second ILD 106 may be formed of a dielectric material, such as PSG, BSG, BPSG, USG, or the like, and may be deposited by any suitable method, such as CVD, PECVD, FCVD, or the like.

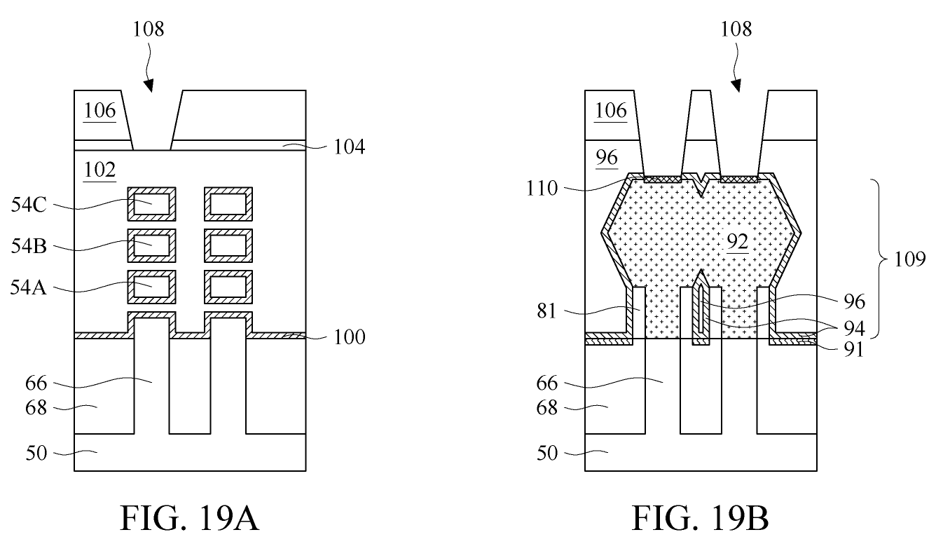

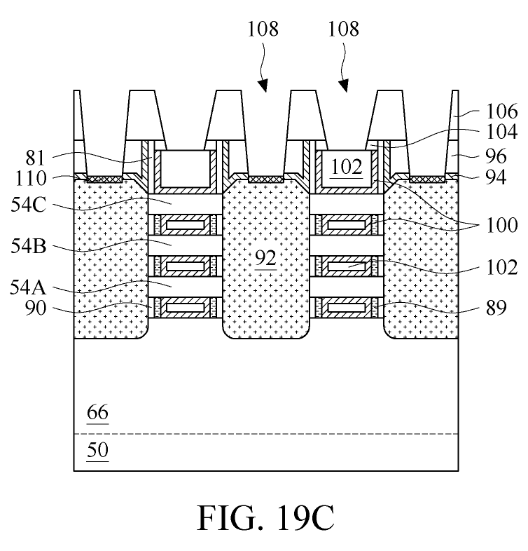

In FIGS. 19A-19C, the second ILD 106, the first ILD 96, the CESL 94, and the gate masks 104 are etched to form fourth recesses 108 exposing surfaces of the epitaxial source/drain regions 92 and/or some of the gate structures. The fourth recesses 108 may be formed by etching using an anisotropic etching process, such as RIE, NBE, or the like. In some embodiments, the fourth recesses 108 may be etched through the second ILD 106 and the first ILD 96 using a first etching process; may be etched through the gate masks 104 using a second etching process; and may then be etched through the CESL 94 using a third etching process. A mask, such as a photoresist, may be formed and patterned over the second ILD 106 to mask portions of the second ILD 106 from the first etching process and the second etching process. In some embodiments, the etching process may over-etch, and therefore, the fourth recesses 108 extend into the epitaxial source/drain regions 92 and/or some of the gate structures, and a bottom of the fourth recesses 108 may be level with (e.g., at a same level, or having a same distance from the substrate 50), or lower than (e.g., closer to the substrate 50) the epitaxial source/drain regions 92 and/or some of the gate structures.

After the fourth recesses 108 are formed, first silicide regions 110 are formed over the epitaxial source/drain regions 92. In some embodiments, the first silicide regions 110 are formed by first depositing a metal (not separately illustrated) capable of reacting with the semiconductor materials of the underlying epitaxial source/drain regions 92 (e.g., silicon, silicon germanium, germanium) to form silicide or germanide regions, such as nickel, cobalt, titanium, tantalum, platinum, tungsten, other noble metals, other refractory metals, rare earth metals or their alloys, over the exposed portions of the epitaxial source/drain regions 92, then performing a thermal annealing process to form the first silicide regions 110. The un-reacted portions of the deposited metal are then removed, e.g., by an etching process. Although the first silicide regions 110 are referred to as silicide regions, the first silicide regions 110 may also be germanide regions, or silicon germanide regions (e.g., regions comprising silicide and germanide).

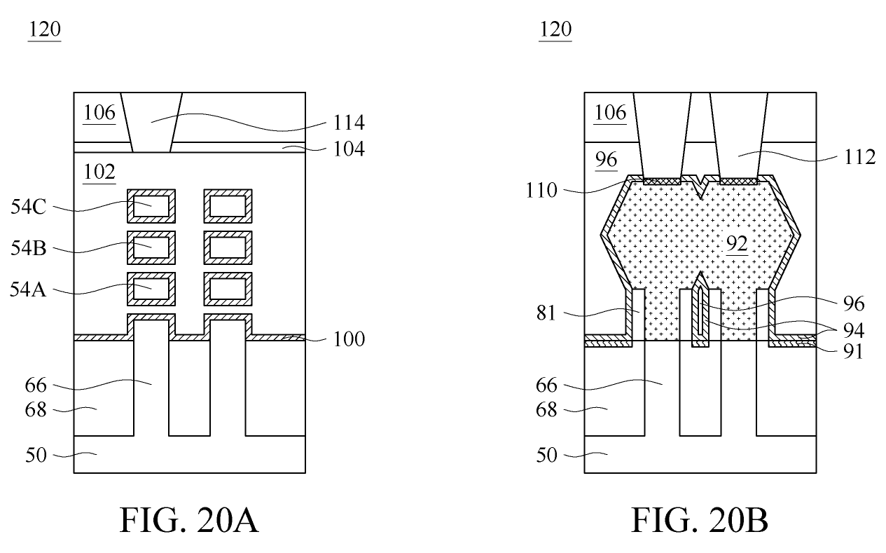

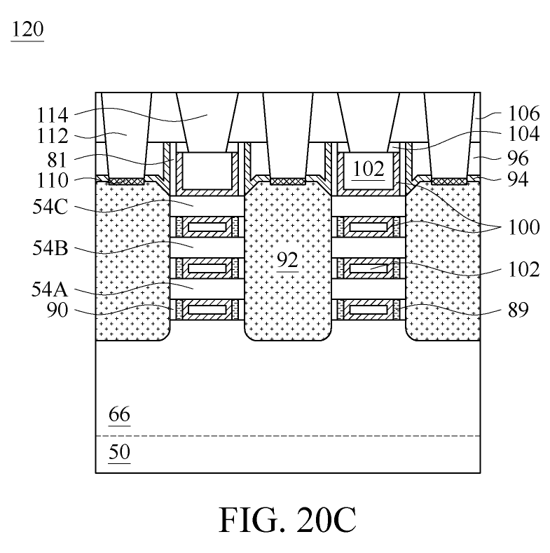

In FIGS. 20A-20C, source/drain contacts 112 and gate contacts 114, which may be also referred to as conductive contacts, are formed in the fourth recesses 108. The source/drain contacts 112 and the gate contacts 114 may each comprise one or more layers, such as barrier layers, diffusion layers, and fill materials. For example, in some embodiments, the source/drain contacts 112 and the gate contacts 114 each include a barrier layer and a conductive material, and are each electrically connected to an underlying conductive feature (e.g., a gate electrode 102 and/or a first silicide region 110). The gate contacts 114 are electrically connected to the gate electrodes 102 and the source/drain contacts 112 are electrically connected to the first silicide regions 110. The barrier layer may include titanium, titanium nitride, tantalum, tantalum nitride, or the like. The conductive material may be copper, a copper alloy, silver, gold, tungsten, cobalt, aluminum, nickel, or the like. A planarization process, such as CMP, may be performed to remove excess material from surfaces of the second ILD 106. The structure shown in FIGS. 20A-20C may be referred to as semiconductor device 120.

The embodiments of the present disclosure have some advantageous features. By forming the protective layers 89, the inner spacers 90 and the epitaxial source/drain regions 92 may be protected during the etching processes, and sufficient electrical insulation between the epitaxial source/drain regions 92 and the gate structures may be provided, which may reduce or eliminate the parasitic capacitance between the epitaxial source/drain regions 92 and the gate structures. As a result, the performance and reliability of the semiconductor device 120 may be improved.

In an embodiment, a semiconductor device includes a first nanostructure and a second nanostructure, wherein the first nanostructure and the second nanostructure are vertically stacked; a gate structure between the first nanostructure and the second nanostructure; a first dielectric layer on a sidewall of the gate structure, wherein the first dielectric layer includes a first material; and a second dielectric layer on the first dielectric layer, wherein the second dielectric layer includes a second material different from the first material, and wherein the second dielectric layer is in contact with the first nanostructure and the second nanostructure. In an embodiment, the first material has a first dielectric constant and the second material has a second dielectric constant, and wherein the second dielectric constant is smaller than the first dielectric constant. In an embodiment, the first material has a first dielectric constant in a range from 5 to 7. In an embodiment, the first material is silicon oxynitride, and wherein the second material is silicon nitride. In an embodiment, the first dielectric layer has a thickness in a range from 1 nm to 2 nm. In an embodiment, the semiconductor device further includes a protrusion underneath the first nanostructure and the second nanostructure; an isolation region along a sidewall of the protrusion; and a third dielectric layer on the isolation region and a fourth dielectric layer on the third dielectric layer, wherein the third dielectric layer includes a third material and the fourth dielectric layer includes a fourth material, and wherein the third material has a different material composition from the fourth material. In an embodiment, the third material has a same material composition as the first material.

In an embodiment, a semiconductor device includes a first nanostructure and a second nanostructure; a gate structure between the first nanostructure and the second nanostructure; a first dielectric layer on a sidewall of the gate structure, wherein the first dielectric layer includes a first material; a second dielectric layer on the first dielectric layer, wherein the second dielectric layer includes a second material, and wherein the second material has a lower dielectric constant than the first material; and a first source/drain region, wherein the first nanostructure, the second nanostructure, and the second dielectric layer are in contact with the first source/drain region, and wherein the first dielectric layer is separated from the first source/drain region by the second dielectric layer. In an embodiment, the first material has a dielectric constant in a range from 5 to 7 and the second material has a dielectric constant smaller than 3.5. In an embodiment, the first material is silicon oxynitride. In an embodiment, the second dielectric layer is in contact with the first nanostructure and the second nanostructure. In an embodiment, the semiconductor device further includes a protrusion underneath the first nanostructure; an isolation region on a sidewall of the protrusion; and a third dielectric layer on the isolation region, wherein a bottom surface of the third dielectric layer is below a top surface of the isolation region and a top surface of the protrusion. In an embodiment, the third dielectric layer includes the first material.

In an embodiment, a method of forming a semiconductor device includes forming a first nanostructure and a second nanostructure over a fin; forming an isolation region along sidewalls of the fin; forming a sacrificial layer between the first nanostructure and the second nanostructure, wherein a sidewall of the sacrificial layer is recessed from sidewalls of the first nanostructure and the second nanostructure, and wherein the sacrificial layer include a first material; converting a portion of the sacrificial layer adjacent the sidewall of the sacrificial layer to a protective layer by a chemical reaction, wherein the protective layer includes a second material different from the first material; forming a spacer layer on the protective layer; and forming a source/drain region, wherein the source/drain region is in contact with the first nanostructure, the second nanostructure, and the spacer layer. In an embodiment, the chemical reaction includes exposing the portion of the sacrificial layer adjacent the sidewall of the sacrificial layer to ammonia plasma. In an embodiment, the first material is silicon oxide and the second material is silicon oxynitride. In an embodiment, the sacrificial layer is in contact with a top surface of the first nanostructure and a bottom surface of the second nanostructure, and wherein the top surface of the first nanostructure and the bottom surface of the second nanostructure remain partially exposed after the chemical reaction. In an embodiment, the method further includes converting a portion of the isolation region adjacent an exposed top surface of the isolation region to a dielectric layer by the chemical reaction, wherein the dielectric layer includes a different material from the isolation region. In an embodiment, the spacer layer has a lower dielectric constant than the protective layer. In an embodiment, the method further includes removing the sacrificial layer and forming a gate structure between the first nanostructure and the second nanostructure, wherein the gate structure is in contact with the protective layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device comprising:
a plurality of nanostructures vertically stacked and spaced apart from one another;
a gate structure comprising a plurality of portions, the portions between adjacent pairs of the nanostructures;
a plurality of first dielectric layers, the first dielectric layers on sidewalls of the portions of the gate structure, wherein the first dielectric layers comprises a first material;
a plurality of second dielectric layers, the second dielectric layers on the first dielectric layers, wherein the second dielectric layers comprises a second material having a lower dielectric constant than the first material, and wherein the second dielectric layers are in contact with the adjacent pairs of the nanostructures; and
a source/drain region in contact with the nanostructures and the second dielectric layers, wherein the first dielectric layers are separated from the source/drain region by the second dielectric layers.

2. The semiconductor device of claim 1 wherein the first material is silicon oxynitride and the second material is silicon nitride.

3. The semiconductor device of claim 1, wherein the first material has a dielectric constant in a range from 5 to 7, and wherein the second material has a dielectric constant less than 3.5.

4. The semiconductor device of claim 1, further comprising a fin under the nanostructures and an isolation region along a sidewall of the fin.

5. The semiconductor device of claim 4, further comprising a third dielectric layer on the isolation region and a fourth dielectric layer on the third dielectric layer, wherein the third dielectric layer comprises a third material and the fourth dielectric layer comprises a fourth material, and wherein the third material has a different material composition from the fourth material.

6. The semiconductor device of claim 5, wherein the third material has a same material composition as the first material.

7. The semiconductor device of claim 5, wherein a bottom surface of the third dielectric layer is below a top surface of the isolation region and a top surface of the fin.

8. The semiconductor device of claim 1, wherein the source/drain region comprises a first liner layer on sidewalls of the nanostructures, a second liner layer on the first liner layer, and a fill layer on the second liner layer.

9. A method of forming a semiconductor device, the method comprising:
forming a first nanostructure and a second nanostructure over a fin;
forming an isolation region along a sidewall of the fin;
forming a sacrificial layer between the first nanostructure and the second nanostructure, wherein the sacrificial layer comprises a first material;
exposing the sacrificial layer and the isolation region to a plasma, wherein the plasma converts a portion of the sacrificial layer adjacent a sidewall of the sacrificial layer to a protective layer and converts a portion of the isolation region adjacent an exposed surface of the isolation region to a dielectric layer, wherein the protective layer comprises a second material different from the first material, and wherein the dielectric layer comprises a material different from a material of the isolation region;
forming a spacer layer on the protective layer; and
forming a source/drain region in contact with the first nanostructure, the second nanostructure, and the spacer layer.

10. The method of claim 9, wherein the plasma comprises ammonia plasma.

11. The method of claim 9, wherein the first material is silicon oxide and the second material is silicon oxynitride.

12. The method of claim 9, wherein the protective layer has a thickness in a range from 2 nm to 3 nm, wherein the dielectric layer has a thickness in a range from 1 nm to 2 nm, and wherein the thickness of the protective layer is greater than the thickness of the dielectric layer.

13. The method of claim 9, wherein the sacrificial layer is in contact with a top surface of the first nanostructure and a bottom surface of the second nanostructure, and wherein the top surface of the first nanostructure and the bottom surface of the second nanostructure remain partially exposed after the plasma converts the portion of the sacrificial layer.

14. The method of claim 9, wherein the spacer layer has a lower dielectric constant than the protective layer.

15. The method of claim 9, further comprising, before exposing the sacrificial layer and the isolation region to the plasma, recessing the sidewall of the sacrificial layer from sidewalls of the first nanostructure and the second nanostructure.

16. A method of forming a semiconductor device, the method comprising:
forming a first nanostructure and a second nanostructure;
forming a sacrificial layer between the first nanostructure and the second nanostructure, wherein the sacrificial layer comprises a first material;
converting a portion of the sacrificial layer to a protective layer, wherein the protective layer comprises a second material different from the first material;
forming an inner spacer on the protective layer;
forming a source/drain region in contact with the first nanostructure, the second nanostructure, and the inner spacer;
removing the sacrificial layer by an etching process, wherein the protective layer protects the inner spacer and the source/drain region during the etching process; and
forming a gate structure between the first nanostructure and the second nanostructure, wherein the gate structure is in contact with the protective layer.

17. The method of claim 16, wherein converting the portion of the sacrificial layer comprises exposing the sacrificial layer to a plasma to convert the portion of the sacrificial layer by a chemical reaction.

18. The method of claim 16, wherein the first material is silicon oxide and the second material is silicon oxynitride.

19. The method of claim 16, wherein the inner spacer has a lower dielectric constant than the protective layer.

20. The method of claim 16, wherein the inner spacer separates the protective layer from the source/drain region.
